(19) United States
(12) Patent Application Publication
(10) Pub. No.: US 2006/0137862 A1
(43) Pub. Date: Jun. 29, 2006

(54) Heat dissipating device with metal foam

(75) Inventors: Ching-Bai Huang, Tu-Cheng (TW); Xi-Jian Zhu, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: Foxconn Technology CO., LTD., Tu-Cheng City (TW)

(21) Appl. No.: 11/166,662

(22) Filed: Jun. 24, 2005

(30) Foreign Application Priority Data
Dec. 24, 2004 (TW) 93140461

(51) Int. Cl. F28D 15/00; H05K 7/20

(52) U.S. Cl. 165/104.33; 361/700; 165/907

(57) ABSTRACT

A heat dissipating device for removing heat from a heat-generating electronic component includes at least one heat transfer device and metal foams combined to the heat transfer device. The heat transfer device may be a heat pipe. The heat generated by the electronic component is transferred to the metal foams through the heat transfer device. The metal foams are used for dissipating the heat to atmosphere.

### TECHNICAL FIELD

The present invention relates generally to a heat dissipating device, and more particularly to a heat dissipating device which can be suitably applied to remove heat from heat-generating electronic components.

### BACKGROUND

As technological progress is continuously made in electronic industries, electronic devices such as central processing units (CPUs) of computers are becoming more and more powerful. Accordingly, the amount of heat generated by the CPUs increases noticeably. However, the performance and stability of the CPUs strongly depend on their ability to effectively remove the generated heat. To this regard, a variety of conventional heat dissipating devices have been designed for dissipating heat from the CPUs, by thermal conduction, convection, or radiation.

A conventional heat dissipating device generally includes a metal base for contacting and absorbing heat from a CPU, a heat pipe with one end thereof attached to the base, and a plurality of fins attached to the other end of the heat pipe. By this configuration, the heat generated by the CPU is removed by conducting to the base and further conducting by the heat pipe to the fins where the heat is dissipated. In the fabrication process of the heat dissipating device, an additional combination step is often required to combine the fins to the heat pipe, and in most cases, the fins are combined to the heat pipe by soldering process, or by the heat pipe interferentially engaging with the fins. However, the combination step will increase the manufacturing cost to the heat dissipating device additionally, and will inevitably result in between the fins and the heat pipe large thermal resistance which greatly reduce the heat transfer effect of the heat dissipating device. Furthermore, if the heat dissipating device is applied to a notebook computer, the number of fins and the total heat transfer surface area of the fins are extremely limited due to the limited space provided for installation of the heat dissipating device inside the notebook. In this situation, it may lead to the fact that the heat generated by the notebook cannot be effectively removed.

In view of the above-mentioned disadvantages of the conventional heat dissipating device, there is a need for providing a heat dissipating device capable of dissipating heat effectively from heat-generating electronic components.

### SUMMARY

The present invention relates to a heat dissipating device for removing heat from a heat-generating electronic component. In one embodiment, the heat dissipating device includes at least one heat transfer device and metal foams combined to the heat transfer device. The heat transfer device may be a heat pipe. The heat generated by the electronic component is transferred to the metal foams through the heat transfer device.

Compared with conventional heat dissipating devices, the heat dissipating device of the present invention has many advantages. The metal foams can be simultaneously combined to the heat transfer device when the metal foams are fabricated, thereby reducing undesirable thermal resistance between the metal foams and the heat transfer device. Furthermore, the metal foams can be made to have a compact structure meanwhile providing a large heat transfer area. This feature enables the heat dissipating device to be suitably applied to notebook computers in which limited spaces are provided for mounting the heat dissipating devices.

Other advantages and novel features of the present invention will become more apparent from the following detailed description of the preferred embodiment when taken in conjunction with the accompanying drawings, in which:

### BRIEF DESCRIPTION OF THE DRAWINGS

FIG. 1 is a schematic side elevation view of a heat dissipating device in accordance with a first embodiment of the present invention;

FIG. 2 is a schematic side elevation view of a heat dissipating device in accordance with a second embodiment of the present invention;

FIG. 3 is a schematic side elevation view of a heat dissipating device in accordance with a third embodiment of the present invention;

FIG. 4 is a schematic y side elevation view of a heat dissipating device in accordance with a fourth embodiment of the present invention;

FIG. 5 is a schematic side elevation view of a heat dissipating device in accordance with a fifth embodiment of the present invention;

FIG. 6 is a schematic side elevation view of a heat dissipating device in accordance with a sixth embodiment of the present invention;

FIG. 7 is a schematic cross-sectional view of a heat dissipating device in accordance with a seventh embodiment of the present invention; and

FIG. 8 is a schematic cross-sectional view of a heat dissipating device in accordance with an eighth embodiment of the present invention.

### DETAILED DESCRIPTION OF THE PREFERRED EMBODIMENT

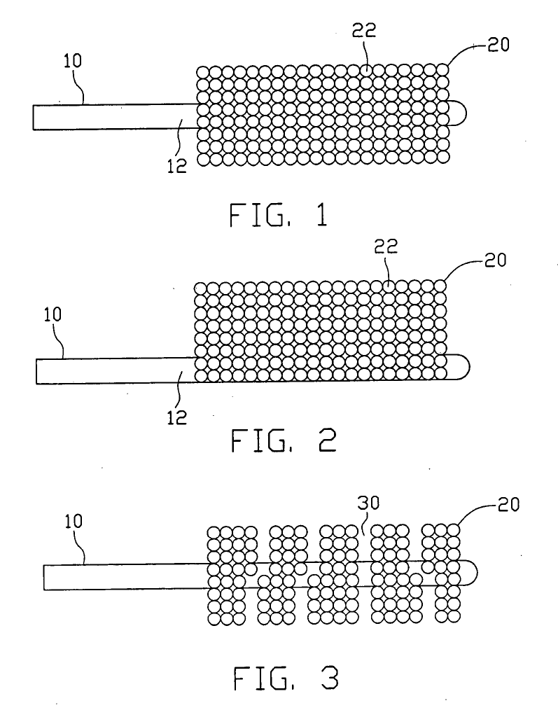

FIG. 1 schematically shows a heat dissipating device in accordance with a first embodiment of the present invention. The heat dissipating device includes a heat transfer device 10 and metal foams 20 combined to an outer surface of the heat transfer device 10. The heat transfer device 10 can be a rounded heat pipe, a loop-type heat pipe, a pulsating heat pipe (PHP) or a solid column made of thermally conductive metal materials such as copper, copper alloy, aluminum, and so on. The heat transfer device 10 has an elongated body portion 12 and the metal foams 20 are combined to one end of the body portion 12. The metal foams 20 are porous and may be made of such materials as stainless steel, copper, copper alloy, aluminum alloy and silver.

The metal foams 20 are combined to one end of the heat transfer device 10 by surrounding a periphery of the body portion 12 and extending outwardly from the periphery. As exaggeratingly shown, the metal foams 20 have a network of metal ligaments or wires forming numerous open cells 22 to provide porosity. The cells 22 may be randomly distributed throughout the metal foams 20. The metal foams. 20 have a compact structure in combination with large surface area. The maximum surface area of the metal foams 20 can approximately reach to 10⁴ m²/m³ (ligaments surface area/metal foams volume).

The metal foams 20 are fabricated by expanding and solidifying a pool of liquid metal saturated with an inert gas under pressure. Density of the porous metal is varied by applying different levels of pressure. The porosity of the foam after solidification may be in a wide range with the open cells 20 randomly distributed over the metal foams 20. Electroforming is a typical method for fabricating metal foam, which generally involves steps of providing one kind of porous material such as polyurethane foam, then electrodepositing a layer of metal over the surface of the polyurethane foam and finally heating the resulting product at a high temperature to get rid of the polyurethane foam to thereby obtain porous metal foam. Another fabrication method for metal foam, called die-casting process, is also widely used, which generally includes steps of providing one kind of porous material such as polyurethane foam, filling ceramic slurry into the pores of the porous polyurethane foam and then solidifying the ceramic slurry therein, then heating the resulting product at a high temperature to get rid of the polyurethane foam to obtain a matrix of porous ceramic, then filling metal slurry into the pores of the ceramic matrix and finally getting rid of the ceramic material after solidification of the metal slurry to thereby obtain porous metal foam. However, there are still some other methods suitable for fabrication of metal foam. Fox example, the metal foams 20 can be made by steps of filling a kind of bubble-generating material such as metallic hydride into metal slurry to generate a large number of bubbles distributing randomly throughout the metal slurry and solidifying the metal slurry to thereby obtain metal foam with a plurality of pores therein. In order to reduce undesirable thermal resistance between the heat transfer device 10 and the metal foams 20, the metal foams 20 are preferably combined to the heat transfer device 10 simultaneously as the metal foams 20 are fabricated by foregoing methods.

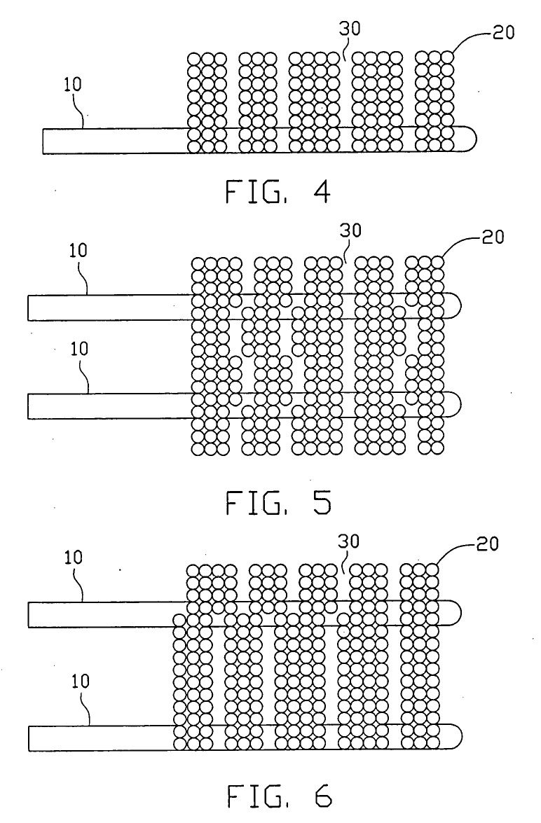

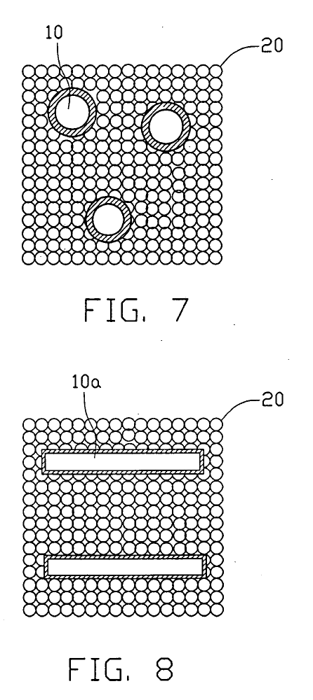

FIGS. 2-8 schematically show heat dissipating devices in accordance with some additional embodiments of the present invention. In FIG. 2, the metal foams 20 extend only from a portion of the periphery of the body portion 12 and are located at one side of the heat transfer device 10. With reference to FIGS. 3-6, a plurality of slits 30 are defined in the metal foams 20 in a direction perpendicular to the body portion 12 for facilitating air exchange through the metal foams 20. In these embodiments, fox example, an electric fan (not shown) may be used to generate an airflow through the slits 30 along the direction perpendicular to the body portion 12 so as to increase heat exchange rate of the metal foams 20. In FIGS. 5-7, more than one heat transfer device 10 is provided and the metal foams 20 are combined simultaneously to these heat transfer devices 10. In FIG. 8, the metal foams 20 are combined to a pair of plate-type heat pipes 10a.

In operation, the other end of the body portion 12 of the heat transfer device 10 may be thermally connected, whether directly or indirectly, to a heat-generating electronic component (not shown). Thus, the heat generated by the electronic component is transferred by the heat transfer device 10 to the metal foams 20 where the heat is finally dissipated to atmosphere. In this case, the metal foams 20 may be attached to the heat transfer device 10 in the fabrication process of the metal foams 20, thereby reducing undesirable thermal resistance between the heat transfer device 10 and the metal foams 20 and eliminating the additional combination step required to combine the heat transfer device 10 with the metal foams 20 if the metal foams 20 are individually fabricated. Further, the metal foams 20 can be made to have a compact structure in combination with large surface area, this feature enabling the heat dissipating device of the present invention to be suitably applied to notebook computers for heat dissipation purpose.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipating device comprising:
a heat pipe; and
metal foams combined to an outer surface of the heat pipe.

2. The heat dissipating device of claim 1, wherein the metal foams are combined to the heat pipe in the fabrication process of the metal foams.

3. The heat dissipating device of claim 2, wherein the metal foams are fabricated by expanding and solidifying a pool of liquid metal saturated with an inert gas under pressure.

4. The heat dissipating device of claim 1, wherein a plurality of slits are defined in the metal foams to enhance air-convection over the metal foams.

5. The heat dissipating device of claim 1, wherein the metal foams extend outwardly from at least a portion of a periphery of the heat pipe.

6. The heat dissipating device of claim 1, wherein the metal foams are combined to a portion of the heat pipe.

7. The heat dissipating device of claim 1, wherein the heat pipe is one of a rounded and a plate-type one.

8. A method for removing heat from an electronic component comprising the steps of:
providing a heat transfer device having an elongated body portion;
combining porous metal foams to one end of the body portion; and
applying the other end of the body portion to be thermally connected to the electronic component to transfer heat from the electronic component to the metal foams via the heat transfer device.

9. The method of claim 8, wherein the heat transfer device is a heat pipe.

10. The method of claim 8, wherein the heat transfer device is a solid column made of heat-conductive material.

11. The method of claim 8, wherein the metal foams are directly combined to the heat transfer device in the fabrication process of the metal foams to reduce thermal resistance formed therebetween.

12. The method of claim 11, wherein the metal foams are fabricated by expanding and solidifying a pool of liquid metal saturated with an inert gas.

13. The method of claim 8, wherein a plurality of slits are defined in the metal foams to enhance air-convection over the metal foams.

14. The method of claim 8, wherein the metal foams surround a periphery of the heat transfer device.

15. A heat dissipation device comprising:
a heat pipe having a first end portion for thermally connecting with a heat-generating component, and a second end portion distant from the first end portion; and
a metal foam thermally connecting with the second end portion for dissipating heat transferred by the heat pipe from the first end portion to the second end portion to atmosphere.

16. The heat dissipation device of claim 15, wherein the heat pipe is one of a round heat pipe and a plat-type heat pipe.

17. The heat dissipation device of claim 15, wherein the metal foam has slits therein extending in a direction perpendicular to the heat pipe.

18. The heat dissipation device of claim 17, wherein airflow flows through the slits along the direction perpendicular to the heat pipe.

19. The heat dissipation device of claim 15, wherein the metal foam contacts at least a portion of a periphery of the heat pipe.

20. The heat dissipation device of claim 15, wherein the metal foam is made by one of die casting and electroforming.
